(19) United States
(12) Patent Application Publication
(10) Pub. No.: US 2026/0101519 A1
(43) Pub. Date: Apr. 9, 2026

(54) HETEROGENEOUS MEMORY STACK

(71) Applicant: PieceMakers Technology, Inc., Hsinchu City (TW)

(72) Inventors: Tah-Kang Joseph Ting, Hsinchu City (TW); Ming-Hung Wang, Hsinchu City (TW)

(73) Assignee: PieceMakers Technology, Inc., Hsinchu City (TW)

(21) Appl. No.: 19/344,539

(22) Filed: Sep. 30, 2025

Related U.S. Application Data
(60) Provisional application No. 63/704,034, filed on Oct. 7, 2024.

(51) Int. Cl. H10B 80/00; H01L 23/00; H01L 25/065; H01L 25/18

(52) U.S. Cl. CPC H10B 80/00; H10W 90/00; H10W 90/297; H10W 90/792

(57) ABSTRACT

A stacked memory device includes a first memory die and a second memory die. The first memory die has multi-layer structure and each of a plurality of layers of the first memory die includes at least a memory cell region and a through-silicon-via (TSV) region. The first memory die is electrically connected to an integrated circuit device through a plurality of vertical interconnects within the TSV region. The second memory die is disposed between the first memory die and the integrated circuit device. The second memory die has single layer structure, and the second memory die includes at least a memory cell region and a TSV region. The second memory die is electrically connected to the integrated circuit device through surface bonding.

### CROSS REFERENCE TO RELATED APPLICATIONS

This application claims the benefit of U.S. Provisional Application No. 63/704,034, filed on October 7th, 2024. The content of the application is incorporated herein by reference.

### BACKGROUND OF THE INVENTION

### 1. FIELD OF THE INVENTION

The present invention relates to semiconductor memories, and more particularly to a three-dimensional heterogeneous stack scheme to stack a multi-layer memory die over a single-layer memory die.

### 2. DESCRIPTION OF THE PRIOR ART

Modern computing systems require increasingly high-performance memory architectures to keep up with the rapid advancements in processor speeds and data-intensive applications. Technologies such as high-bandwidth memory (HBM) and 3D-stacked dynamic random-access memory (3D DRAM) have emerged as solutions to improve memory bandwidth and capacity by leveraging vertical integration techniques. These architectures utilize through-silicon vias (TSVs) to enable inter-die connectivity and reduce data transfer bottlenecks.

However, TSV-based memory stacking architectures require a designated TSV region within each memory die to accommodate vertical interconnects. This TSV region is necessary to house through-silicon vias that provide inter-layer connectivity, but its presence introduces significant design constraints that impact die utilization efficiency. Specifically, the TSV region consumes silicon area that would otherwise be available for memory cells, resulting in a die size penalty.

Accordingly, there is a need for an improved stacked memory device architecture that maximizes memory density while enhancing inter-die connectivity.

### SUMMARY OF THE INVENTION

With this in mind, it is one object of the present invention to provide a hierarchical memory stacking scheme that utilizes a multi-layer memory die for expanded capacity while reserving a single-layer memory die for high-density surface bonding, thereby achieving superior performance in high-bandwidth computing applications.

According to one embodiment, a stacked memory device is provided. The stacked memory device comprises: a first memory die and a second memory die. The first memory die has multi-layer structure and each of a plurality of layers of the first memory die includes at least a memory cell region and a through-silicon-via (TSV) region. The first memory die is electrically connected to an integrated circuit device through a plurality of vertical interconnects within the TSV region. The second memory die is disposed between the first memory die and the integrated circuit device. The second memory die has single layer structure, and the second memory die includes at least a memory cell region and a TSV region. The second memory die is electrically connected to the integrated circuit device through surface bonding.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a cross-section view of a stacked memory device according to one embodiment of the present invention.

FIG. 2 illustrates a floorplan of one of multiple layers of a first memory die of a stacked memory device according to one embodiment of the present invention.

FIG. 3 illustrates a floorplan a second memory die of a stacked memory device according to one embodiment of the present invention.

### DETAILED DESCRIPTION

In the following description, numerous specific details are set forth in order to provide a thorough understanding of the present embodiments. It will be apparent, however, to one having ordinary skill in the art that the specific detail need not be employed to practice the present embodiments. In other instances, well-known materials or methods have not been described in detail in order to avoid obscuring the present embodiments.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

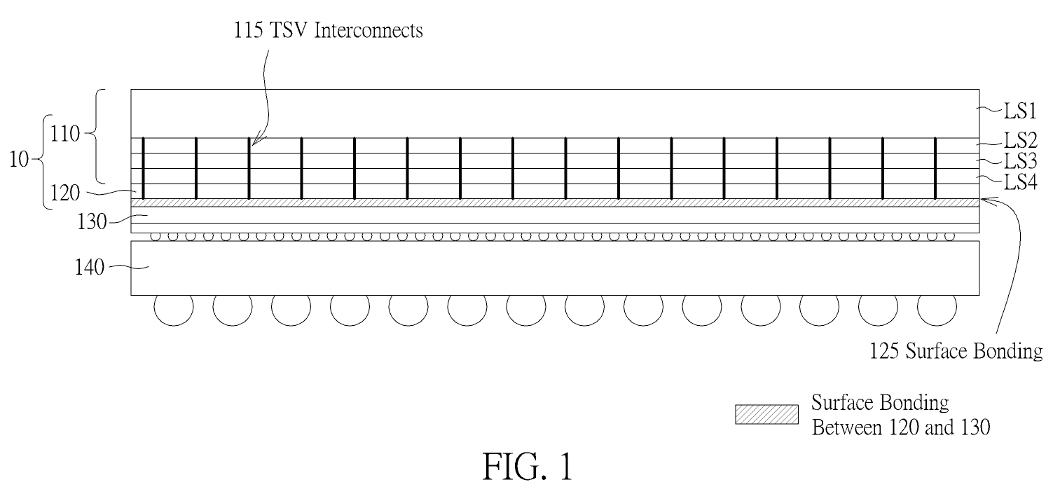

Please refer to FIG. 1, which illustrates a cross-section view of a stacked memory device according to one embodiment of the present invention. In various embodiments, the stacked memory device of the present invention may be implemented in different memory architectures, including, but not limited to, HBM architecture. As illustrated, a stacked memory device 10 is vertically stacked on an integrated circuit device 130, with vertical interconnects provided through TSV structures and surface bonding.

In some embodiments, the integrated circuit device 130 may be implemented as a logic die, including, but not limited to, a central processing unit (CPU) for general-purpose computing application, a graphics processing unit (GPU) for high-performance computing and/or AI applications, a neural processing unit (NPU) for AI inference or training purposes, a field-programmable gate array (FPGA), or an application-specific integrated circuit (ASIC). In other embodiments, the integrated circuit device 130 may be a memory-related controller, a physical layer control unit (PHY), or an HBM logic die. Additionally, the integrated circuit device 130 may be a high-speed interface controller, or part of a heterogeneous multi-chip module (MCM) or three-dimensional integrated circuit (3D IC) architecture. Furthermore, the integrated circuit device 130 may be implemented as a system on chip (SoC), which is electrically connected to a substrate 140 via solder bumps.

The stacked memory device 10 comprises a first memory die 110 and a second memory die 120, each of which may be a semiconductor chip (cut from a wafer). The first memory die 110 has a multi-layer structure, including a plurality of layers LS1-LS4 stacked on the second memory die 120. Please note that, although four layers LS1-LS4 of the first memory die 110 are illustrated in the embodiment of FIG. 1, this is not a limitation of the present invention. According to various embodiments of the present invention, there could be fewer or more layers included in the multi-layer structure of the first memory die 110 depending on design requirements.

Each of the layers LS1-LS4 is electrically connected to the integrated circuit device 130 through a plurality of vertical interconnects 115 within TSV region. As used herein, the term “vertical interconnect” refer to conductive path extending through a semiconductor die, including TSVs formed with conductive fill materials. The vertical interconnects 115 extend through the layers LS1-LS4 of the first memory die 110, providing signal transmission paths between different layers and the integrated circuit device 130. Each of the layers LS1-LS4 of the first memory die 110 may comprise circuitry electrically connected to the vertical interconnects 115. In some embodiments, the vertical interconnects 115 may not penetrate the TSV region of the topmost layer (e.g. layer LS1) of the first memory die 110.

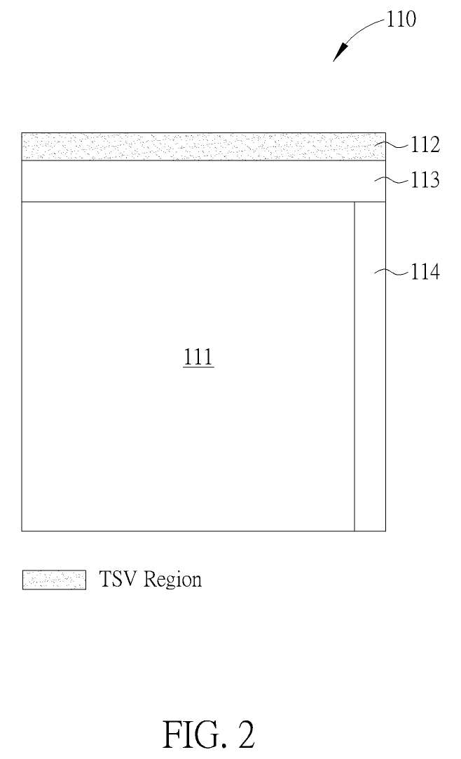

Please refer to FIG. 2 in conjunction with FIG. 1. FIG. 2 illustrates a floorplan of one of multiple layers LS1-LS4 of the first memory die 110. As illustrated, each layer of the first memory die 110 comprises a memory cell region 111 and a TSV region 112. The memory cell region 111 comprises an array of memory cells and the TSV region 112 has holes with the conductive fill materials extending through, forming the vertical interconnects 115 between different layers and the integrated circuit device 130. Each layer of the first memory die 110 further comprises a first circuitry region 113 and a second circuitry region 114. The first circuitry region 113 may comprise peripheral circuitry, configured for input/output operations and control/data signal management. The second circuitry region 114 may comprise decoder circuitry, configured for addressing and accessing memory cells within the memory cell region 111. In some embodiments, the peripheral circuitry of the first circuitry region 113 of each of the layers LS1-LS4 may be electrically connected either directly to the integrated circuit device 130 or to the peripheral circuitry of the first circuitry region 113 of another one of the layers LS1-LS4, enabling signal transmission between different layers before reaching the integrated circuit device 130.

The second memory die 120 has a single-layer structure, and is electrically connected to the integrated circuit device 130 through surface bonding 125, which enables direct electrical interconnection over a whole active area of the second memory die 120. As used herein, the term “surface bonding” refers to a bonding technology that enables direct electrical interconnection between semiconductor dies without the use of solder bumps. Surface bonding techniques may include hybrid bonding, oxide bonding and direct metal bonding (e.g., Cu-Cu bonding).

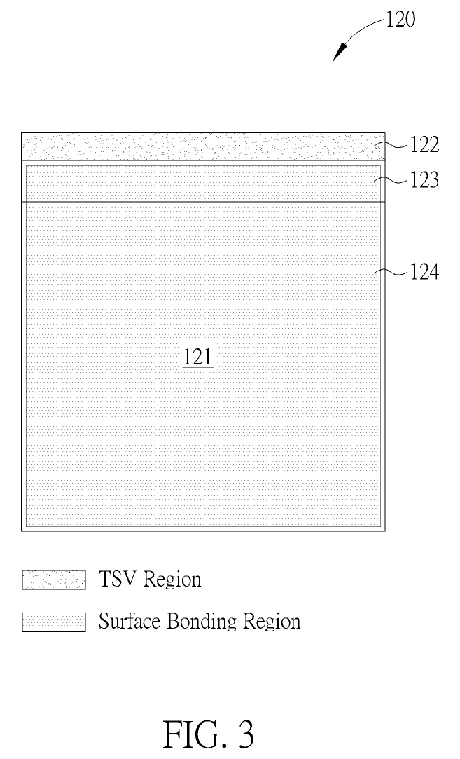

Please refer to FIG. 3 in conjunction with FIG. 1. FIG. 3 illustrates a floorplan of the second memory die 120. As illustrated, the second memory die 120 comprises a memory cell region 121 and a TSV region 122. The memory cell region 121 comprises an array of memory cells. The TSV region 122 includes vertical interconnects 115 that are vertically aligned with the TSV region 112 of the first memory die 110, enabling signal routing between different layers and the integrated circuit device 130. The first circuitry region 123 may comprise peripheral circuitry, configured for input/output operations and control/data signal management. The second circuitry region 124 may comprise decoder circuitry, configured for addressing and accessing memory cells within the memory cell region 121.

Although FIGS. 1-3 illustrate the first memory die 110 and the second memory die 120 as having the same die size, in other embodiments of the present invention, the die sizes of the first memory die 110 and the second memory die 120 may be different. Additionally, while the TSV region 112 of each layer LS1-LS4 in the first memory die 110 is vertically aligned with the TSV region 122 of the second memory die 120 to ensure electrical connectivity via the vertical interconnects 115 extending to the integrated circuit device 130, the exact dimensions of the TSV region 112 in each layer LS1-LS4 do not necessarily have to match the TSV region 122 in the second memory die 120. Moreover, the TSV region 112 within different layers LS1-LS4 of the first memory die 110 may also vary in size.

As illustrated in FIG. 1 and FIG. 3, the whole active area of the second memory die 120 is utilized for implementing surface bonding, allowing for a larger interconnection area compared to the TSV region 112 of the first memory die 110 (as well as the TSV region 122 of the second memory die 120). This enables a higher density of control and data signal paths between the second memory die 120 and the integrated circuit device 130.

In some embodiment, one or more of the vertical interconnects 115 that are originated from the first memory die 110 may form intermediate branching structures to electrically connect to the second memory die 120, enabling selective communication between the first memory die 110 and the second memory die 120. Specifically, control circuitry or buffer circuitry within one or more layers of the first memory die 110 can be selectively interface with corresponding control or buffer circuitry in the second memory die 120.

In conclusion, the stacked memory device of the present invention implements a hierarchical architecture that leverages a multi-layer memory die to expand memory capacity while reserving a single-layer memory die for surface bonding, thereby enabling a high-density interconnection for control and data signal paths to enhance memory bandwidth. By utilizing a first memory die with multiple stacked layers (e.g., LS1-LS4), the stacked memory device maximizes storage density. The integration of a second memory die through surface bonding allows for a significantly larger interconnection area compared to traditional TSV-based vertical interconnects. This configuration not only increases the number of available signal paths but also reduces signal transmission latency by minimizing the reliance on TSVs. Overall, the stacked memory device architecture significantly improves memory scalability, bandwidth efficiency, and interconnect density, making it highly suitable for next-generation computing systems, such as artificial intelligence accelerators, high-performance computing platforms, and advanced system-on-chip designs that demand ultra-high memory throughput and low-latency data access.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A stacked memory device, comprising:
a first memory die having multi-layer structure, each layer including at least a memory cell region and a through-silicon-via (TSV) region, wherein the first memory die is electrically connected to an integrated circuit device through a plurality of vertical interconnects within the TSV region;
a second memory die disposed between the first memory die and the integrated circuit device, having single layer structure, the second memory die including at least a memory cell region and a TSV region, wherein the second memory die is electrically connected to the integrated circuit device through surface bonding.

2. The stacked memory device of claim 1, wherein each layer of the first memory die further comprises a first circuitry region and a second circuitry region; the memory cell region comprises an array of memory cells, the first circuitry region comprises peripheral circuitry, and the second circuitry region comprises decoder circuitry.

3. The stacked memory device of claim 1, wherein the second memory die further comprises a first circuitry region and a second circuitry region; the memory cell region comprises an array of memory cells, the first circuitry region comprises peripheral circuitry, and the second circuitry region comprises decoder circuitry.

4. The stacked memory device of claim 1, wherein a number of signal paths between the first memory die and the integrated circuit device that are provided by the vertical interconnects is less than a number of signal paths between the second memory die and the integrated circuit device that are provided by the surface bonding.

5. The stacked memory device of claim 1, wherein a size of the TSV region of the second memory die is larger than that of each of layers of the first memory die.

6. The stacked memory device of claim 1, wherein a size of the TSV region of the second memory die is smaller than that of each of layers of the first memory die.

7. The stacked memory device of claim 1, wherein the surface bonding may include at least one of hybrid bonding, oxide bonding and direct metal bonding.

8. The memory device of claim 1, wherein the vertical interconnects penetrate through the TSV region of the second memory die.

9. The memory device of claim 1, wherein one or more of vertical interconnects that are originated from the first memory die form intermediate branching structures to electrically connect to the second memory die.
